(19) United States
(12) Patent Application Publication
(10) Pub. No.: US 2007/0241325 A1
(43) Pub. Date: Oct. 18, 2007

(54) Schottky Gate Organic Field Effect Transistor and Fabrication Method of the Same

(75) Inventor: Hidenori Okuzaki, Yamanashi (JP)

Correspondence Address: BIRCH STEWART KOLASCH & BIRCH, PO BOX 747, FALLS CHURCH, VA, 22040-0747, US

(73) Assignee: Yamanashi University, Kofu-shi (JP)

(21) Appl. No.: 11/628,974

(22) PCT Filed: Jun. 9, 2005
(86) PCT No.: PCT/JP05/10583

§ 371 Date: Apr. 20, 2007

(30) Foreign Application Priority Data
Jun. 10, 2004 (JP) 2004-171963

(51) Int. Cl. H01L 51/10; H01L 51/30; H01L 51/40

(52) U.S. Cl. 257/40; 438/99; 257/E51.005; 257/E51.009; 257/E51.03

(57) ABSTRACT

A Schottky gate field effect transistor with high speed and simple structure is provided. The Schottky gate field effect transistor includes: a source, a channel and a drain formed by one organic conductive material, in which the source, channel and drain are formed in a continuous structure within an organic conductor; a gate electrode functioning as a metal gate on one surface of the organic conductor; a Schottky barrier formed by contact between the gate electrode and the organic conductor, in which the region overlapping with the Schottky contact is the channel region.

### TECHNICAL FIELD OF THE INVENTION

This invention relates to a Schottky gate organic field effect transistor (FET) and a fabrication method of the Schottky gate organic field effect transistor.

### BACKGROUND ART

As documents on Schottky gate organic field effect transistors using organic materials, the following documents can be cited: H. E. Katz and Z. Bao, “The Physical Chemistry of Organic Field-Effect Transistors”, J. Phys. Chem., 104, 671 (2000); C. J. Drury, C. M. Mutsaers, C. M. Hart, M. Matters and D. M. deLeeuw, “Low-cost all-polymer integrated circuits”, Appl. Phys. Lett., 73, 108 (1998); H. Sirringhaus, N. Tessler and R. H. Friend, “Integrated Optoelectronic Devices Based on Conjugated Polymers”, Science, 280, 1741 (1998).

Regarding the field effect transistors introduced in these documents, an inorganic semiconductor material such as silicon is used for part of one of the transistors, or an organic semiconductor material is used even for a device of total organic type. A problem in the former case was that, since conventional silicon semiconductor manufacturing processes had to be used for part of the fabrication, the features of an organic electronic device and the fabrication method of it were not be taken full advantage of, and a problem in the latter case was that operating voltages were relatively high.

The present inventor has applied a patent application on an organic field effect transistor having a new structure to solve these problems. The organic field effect transistor of a new structure comprises: a source, channel and drain formed by one organic conductive material, in which the source, channel and drain are formed in a continuous structure within an organic conductor; a conductor functioning as a gate through an insulator on one surface of the organic conductor, in which the region of the organic conductor overlapping with the conductor becomes the channel region; and having the organic conductor and the conductor on one substrate (Patent Document 1).

The organic field effect transistor of a new structure involves providing an innovative technology to open a new field of lightweight, flexible and inexpensive plastic electronics. However, it is desirable for such an organic field effect transistor to have more simple structure, easier fabrication processes, and high switching speed.

A Schottky gate organic field effect transistor has more simple structure than a normal organic field effect transistor due to not having an insulator between a gate and a channel.

There is a document below on a Schottky gate organic field effect transistor fabricated by connecting an organic conductive material with a metal material, and forming a Schottky barrier as a gate of the transistor (Non-patent Document 1). The document discloses a technology on an organic field effect transistor of normally-on type as forming a striped electrode on an organic conductive material (Poly(3-alkylhiophene) and applying voltages to the gate electrode. However, the transistor characteristics reported in the document reveal a problem that the current (Isd) between the source and drain is very low such as dozens of nA shown in FIG. 2 of the document.

One of the technologies to easily fabricate an organic transistor is to print the wiring pattern of the transistor using a printer (line patterning technology). The Patent Document 2 below discloses such a line patterning technology. However, in order to apply the line patterning technology disclosed in Patent Document 2 to Schottky gate organic field effect transistors, there are some areas need to be improved on such as how to form a Schottky contact and an ohmic contact by the line patterning technology.
Non-patent Document 1: “Fabrication and Characteristics Gated Poly(3-alkylhiophene) Field Effect Transistors”, Japanese Journal of Applied Physics, Vol. 4A, April 1991
Patent Document 1: Japanese patent application publication No. 2004-140333
Patent Document 2: U.S. patent application publication No. 2002/0083858

### DESCRIPTION OF THE INVENTION

### Problems to be Solved by the Invention

The invention is intended to provide a Schottky gate organic field effect transistor with high speed and with the structure to be easily fabricated.

Also, the invention is intended to provide a method for the easy fabrication of the Schottky gate organic field effect transistor using a commercially available printer.

### MEANS OF SOLVING THE PROBLEMS

In this disclosure document, the term “field effect” is used in the widest sense of controlling a current flow through a channel between a source and a drain, which current flow is driven by the field caused by a voltage applied to a gate (otherwise part or region equivalent to a gate).

The present invention is a Schottky gate field effect transistor comprising a channel between a source and a drain formed by a conductor; a gate formed by a metal to which a voltage controlling a current flow through the channel is applied, in which the source, the drain and the channel are formed by an organic conductive material; and a Schottky barrier formed on the channel region by contact between the organic conductive material of the channel and the metal.

It is preferable for the organic conductive material of the source, drain and channel to have a carrier density of 10¹⁸/cm³ or more. Additionally, though the upper limit of the carrier density varies depending on the molecular size of a dopant and on the contribution rate of carrier generation by a doped dopant, the limit is mostly 10²³/cm³. And, the mobility of the transistor is from 0.1 to 10 cm²/Vs.

It is only necessary for the channel to be formed so that a current path can be formed between the source and the drain.

The source, drain, channel and gate can be expressed as source region/part, drain region/part, channel region/part, and gate region/part respectively, depending on the situation.

An organic conductor is most commonly obtained by doping a dopant (electron-attracting or electron-donating substance) into an organic semiconductor (that is, a dopant-doped semiconductor). Examples of organic semiconductors include polythiophene, polypyrrole, polyaniline, polyacetylene, polydiacetylene, polyphenylene, polyfuran, polyselenophene, polytellurophene, polyisothianaphthene, polyphenylene sulfide, polyphenylenevinylene, polythienylenevinylene, polynaphthalene, polyanthracene, polypyrene, polyazulene, polyfluorene, polypyridine, polyquinoline, polyquinoxaline, polyethylenedioxythiophene, and at least one selected from the derivatives of them. Among them, polyethylenedioxythiophene with high stability and reliability is preferable.

Examples of dopants include iodine, perchloric acid, hydrochloric acid, sulfuric acid, nitric acid, phosphoric acid, boric tetrafluoride, arsenic pentafluoride, hexafluorophosphate, alkylsulfonic acid, perfluoroalkylsulfonic acid, polyacrylic acid, and polystyrene sulfonic acid. These organic semiconductors and dopants can be arbitrarily combined. The carrier density can be controlled by doping a dopant.

An organic conductor includes an organic conductive layer and an organic conductive film, which can be either an n-type organic conductor or a p-type organic conductor. The following is used for a dopant to fabricate a channel as an n-type organic conductor: an alkali metal such as lithium, sodium, potassium, cesium and rubidium, or an ammonium ion such as tetraethylammonium ion and tetrabutylammonium ion.

On the other hand, the following is used for a dopant to fabricate a channel as a p-type organic conductor: vitriolic acid, hydrochloric acid, nitric acid, phosphoric acid, iodine, bromine, arsenic fluoride, perchloric acid, tetrafluoroborate, hexafluorophosphate, alkylbenzenesulfonic acid, alkylsulfonic acid, perfluorosulfonic acid, polystyrene sulfonic acid, polyacrylic acid, methacrylic acid, or one selected from the derivatives of them. Among them, polystyrene sulfonic acid with high stability and reproducibility is preferable.

A requirement for forming a Schottky barrier on a channel region by a Schottky contact is that the work function of a metal material used for a gate is greater than that of an n-type organic conductor, or smaller than that of p-type organic conductor. Also, when PEDOT/PSS is used as an organic conductive material, it is preferable that the average surface roughness Rₐ of the interface between a channel region and a gate electrode is 2.5 nm or less.

Examples of metals used for a gate include aluminum, gold, silver, calcium, cesium, potassium, sodium, rubidium, copper, iron, nickel, titanium, magnesium, scandium, vanadium, manganese, cobalt, ruthenium, cadmium, indium, scandium, tungsten, palladium, zinc, lead, chromium, platinum, and at least one selected from the derivatives of these alloyed metals.

One of these metals is made to be in direct contact on an organic conductive material equivalent to a channel by a method such as vacuum deposition, electrolytic plating and nonelectrolytic plating, as a result of which a Schottky contact is formed by a metal-‘organic conductor’ contact. Among the aforementioned metals, it is more preferable to use an aluminum thin film formed by a vacuum deposition method due to the versatility and the ease in device fabrication.

A substrate can be formed of either an organic material or an inorganic material with use of an insulator or a conductor (otherwise semiconductor) depending on the state of a Schottky gate organic field effect transistor. For example, in the case of supporting an organic conductor on a substrate, an insulator (or one at least with an insulating layer formed on the surface) is used as the substrate. Otherwise, after forming an insulating layer on a conductive substrate, on which an organic conductive layer can be formed. Further, an organic conductor itself can be used as a substrate (to fill both roles as an organic conductor and a substrate). These conditions are included in the definition of substrate such as a substrate supporting an organic conductor, or a substrate on which an organic conductor is being placed.

Also, after supporting a metal electrode on a substrate, on which an organic conductor can be formed. Most commonly, an organic conductor and a metal electrode are formed in layers or films, which are stacked on a substrate.

The most common characteristic of the Schottky gate organic field effect transistor of the present invention is that a current can flow through the channel of organic conductor in a state of not applying a voltage to the metal electrode (gate) (normally-on). But a Schottky gate organic field effect transistor in which no current flows through the channel of organic conductor in a state of not applying a voltage (normally-off) can also be fabricated by increasing the depth (thickness) of the Schottky barrier to the depth (thickness) of the channel or more in a state of not applying a voltage.

Since both can control a current flow through the channel by a voltage applied to the gate, the Schottky gate organic field effect transistor of the present invention functions as a switching device and an amplifying device.

In this way, the invention enables to form a source, channel and drain in a continuous structure using one organic conductor, in which an organic conductor and a metal electrode are supported on one substrate, and therefore the structure is simple and the fabrication is easy.

In one embodiment, the Schottky gate organic field effect transistor of the present invention operates at a low operating voltage, and achieves a switching function with a voltage applied to a conductor functioning as a gate in the range from −5 to 5 V. Also, it ensures that the on/off ratio is 100 or more.

Excepting particular cases, there are typically two types of fabrication methods. The first method is to stack an organic conductive layer and a metal electrode layer on a substrate in this order, and the second method is to stack a metal electrode layer and an organic conductive layer on a substrate in this order.

To define the first fabrication method specifically, this fabrication method is to form an organic conductive layer so that the regions functioning as a source, channel and drain are in a continuous structure on one insulating substrate, and then to form a metal electrode layer to be a gate so as to cover at least the region functioning the channel (excepting at least a part of the regions functioning as the source and the drain) on the organic conductive layer. A source electrode and a drain electrode are formed on the region functioning as the source and on the region functioning as the drain using the same metal as for the metal electrode layer to be the gate. In order to allow the contact surface of the gate electrode to be a Schottky contact using poly(3,4-ethylenedioxythiophene: PEDOT/PSS) as an organic conductive material, it is only required that the average surface roughness of the contact surface of the channel region and/or the gate electrode, Rₐ is 2.5 nm or less. Also, when the average surface roughness of the contact surface of the source region and/or the source electrode, and the average surface roughness of the contact surface of the drain region and/or the drain electrode, Rₐ is 3 nm or more, each contact surface is to be an ohmic contact.

To explain the fabrication method above more specifically, for example, the first pattern is formed and printed on one substrate with an insulating surface using a printing material soluble in a solvent so that the printing material is printed on the regions other than the regions functioning as the source, channel and drain.

Then, a solution in which an organic conductive material dissolves is applied to the whole surface printed with at least the first pattern on the substrate, the substrate is cleaned by a solvent, and the printing material and unnecessary organic conductive material (the material other than the organic conductive material on the source, channel and drain regions) are peeled off. The organic conductive material applied on the printing material is easily peeled off by cleaning due to not adhering to the substrate.

Then, the second pattern is formed and printed using the printing material so that the printing material is printed on the region other than the region functioning as the channel. And then, the substrate is cleaned by a solvent, whereby the printing material is peeled off. As a result, the average surface roughness Rₐ of the source and drain regions becomes 3 nm or more.

And then, a negative pattern of the third pattern specifying the source electrode on the source region, the gate electrode functioning as a gate on the channel region, and the drain electrode on the drain region is printed, a metal material is evaporated so as to cover at least the third pattern, and then the substrate is cleaned. Thereby the source electrode on the source region, the gate electrode on the channel region, and the drain electrode on the drain region are formed, and each contact surface between the source region and the source electrode and between the drain region and the drain electrode is an ohmic contact. Then a Schottky gate field effect transistor, in which the contact surface between the channel region and the gate electrode is a Schottky contact, can be fabricated.

Thus, a Schottky gate field effect transistor can be fabricated by at least three patterning processes: the pattering of an organic conductive layer, the pattering of determining whether a contact is Schottky or ohmic, and the pattering of a metal electrode layer.

To explain the second fabrication method specifically, this fabrication method is to form each metal electrode layer functioning as a source, gate, drain respectively so as not to overlap with the others on one substrate with at least an insulating surface. Each metal to form a source, channel and drain can be the same as the others, it is only required to select a metal having a work function necessary for forming a Schottky contact on a channel region.

An organic conductive layer is formed by applying PEDOT/PSS on each metal electrode layer so as to cover each electrode layer of a source, gate and drain and to allow the regions functioning as a source, channel and drain to be in a continuous structure. In order to allow the contact surface of the gate electrode to be a Schottky contact, it is only required that the average surface roughness of the contact surface of the gate electrode and/or the channel, Rₐ is 2.5 nm or less. In order to allow each contact surface of the source electrode and the drain electrode to be an ohmic contact, it is only required that the average surface roughness of the contact surface of the source electrode and/or the source region, and the average surface roughness of the contact surface of the drain electrode and/or the drain region, Rₐ is 3 nm or more.

To explain the second fabrication method more specifically, a pattern is formed and printed on one substrate with an insulating surface using a printing material soluble in a solvent so that the printing material is printed on the regions other than the regions functioning as source, channel and drain electrodes.

Then, after a metal is evaporated on the whole surface printed with the pattern, the substrate is cleaned by a solvent and thereby source, gate and drain electrodes are formed. And, each surface of the source and drain electrodes is roughened by a plasma or etching treatment. When PEDOT/PSS is used as an organic conductive material, it is only required that the average surface roughness of each contact surface of the source and drain electrodes is 3 nm or more, and the average surface roughness of the contact surface of the gate electrode is 2.5 nm or less.

And then, a solution in which an organic conductive material dissolves is applied to the surface of which the electrode layer is formed so as to allow the regions functioning as the source, channel and drain to be in a continuous structure. In this way, a Schottky gate field effect transistor can be fabricated, in which a Schottky contact electrode is formed on the channel region, and ohmic contact electrodes are formed on the source and drain regions.

It is preferable that the printing is performed by a laser printer and the printing material is toner. Also, it is preferable that the metal material is aluminum.

In the present invention, there is no insulating layer compared to the conventional organic field effect transistor comprising a metal-insulator-‘organic conductor’ contact, therefore the structure is simple and the fabrication is easy. For this reason, a Schottky gate field effect transistor can be fabricated more easily, for example, using a commercially available laser printer.

### BRIEF DESCRIPTION OF THE DRAWINGS

FIG. 1 is structure diagrams of a top gate type of Schottky gate organic field effect transistor in the embodiment;

FIG. 2 is structure diagrams of a bottom gate type of Schottky gate organic field effect transistor in the embodiment;

FIG. 3 illustrates the fabrication process of a Schottky gate organic field effect transistor in the embodiment;

FIG. 4 is a graph showing the drain voltage-current characteristics of a Schottky gate organic field effect transistor;

FIG. 5 is illustrative diagrams speculating on the principle of operation of a Schottky gate organic field effect transistor when the gate voltage is 0 V in the embodiment;

FIG. 6 is illustrative diagrams speculating on the principle of operation of a Schottky gate organic field effect transistor when positive voltage is applied in the embodiment;

FIG. 7 is illustrative diagrams speculating on the principle of operation of a Schottky gate organic field effect transistor when negative voltage is applied in the embodiment;

FIG. 8 is graphs showing the relationship between average surface roughness Rₐ and contact state of interface;

FIG. 9 is a graph showing the dependence of carrier density (NA) on gate voltage (VG);

FIG. 10 is a graph showing the dependence of carrier mobility (g) on gate voltage.

### DESCRIPTION OF THE REFERENCE NUMERALS

10: substrate
20: organic conductive layer
21, 21A: source
22, 22A: channel
23, 23A: drain
30, 30A: gate electrode

### DESCRIPTION OF A PREFERRED EMBODIMENT

### Embodiment 1

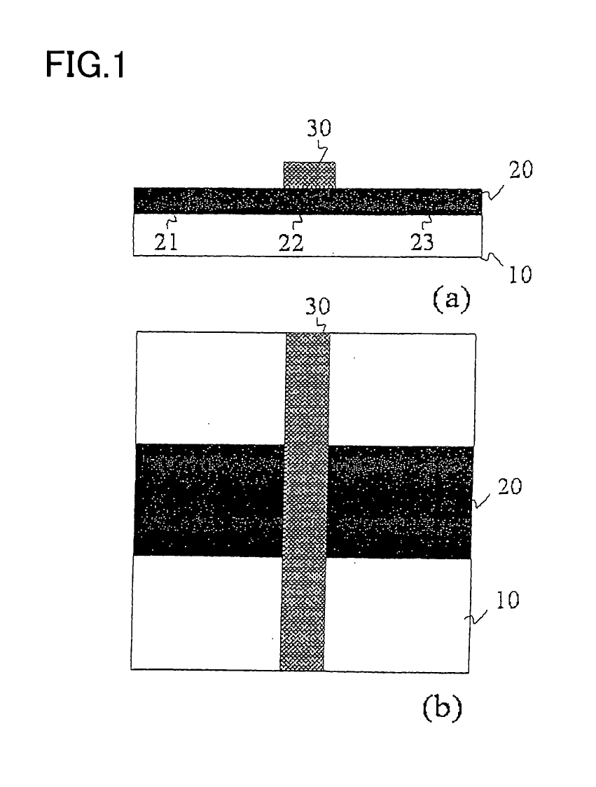

FIG. 1 (a) illustrates a top gate type (the working electrode as a gate is on the channel) structure of Schottky gate organic field effect transistors. The source 21, channel 22 and drain 23 are fabricated on the substrate 10 that has at least an insulating surface. The source 21, channel 22 and drain 23 are made using the same organic conductive material, and are in a continuous structure. A 100 μm thick PET (poly(ethyleneterephthalate)) film is used for the substrate 10, and poly(3,4-ethylenedioxythiophene) doped with poly(4-styrenesulfonate) is used for the source 21, channel 22 and drain 23.

The gate electrode 30 is formed on the region of the channel 22 by vacuum deposition. The gate electrode 30 is formed in a strip on the region of the channel 22. The width of the channel 22 is 1 mm, the length is 100 μm, the height is from 25 to 40 μm. FIG. 1 (b) is a plan view of the transistor.

In the embodiment, polyethylene terephthalate (PET, 100 μm thick OHP film, Tochiman Co. Ltd.) was used, but at least one of the followings can be used: a polyolefin such as polyethylene or polypropylene, a polyamide such as nylon 6 or nylon 66, a polyester such as polyethylene terephthalate or polyethylene naphthalate, an acrylic resin such as polymethylmethacrylate, a metal or inorganic semiconductor having an insulating surface such as polyvinyl alcohol, polyacrylonitrile, polyimide, glass or SiO₂.

Although PEDOT/PSS was used for the channel 22 as well as the source and drain, a metal or different organic conductor can be used for the source and drain, and the invention is not limited to it.

Also, the substrate 10 was used, but an organic conductor, PEDOT/PSS itself can be used as the substrate 10, or the source, channel, drain layer can be used as the substrate. As to the substrate disclosed in this disclosure, the conditions above are included in the definition of substrate such as a substrate supporting an organic conductor, or a substrate on which an organic conductor is being placed.

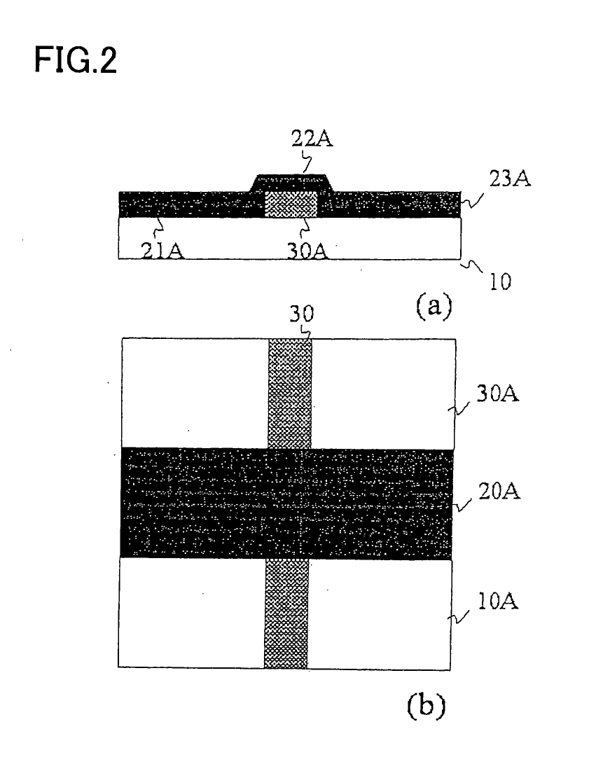

FIG. 2 (a) illustrates a bottom gate type structure of Schottky gate organic field effect transistors. The source 21A, gate electrode 30A and drain 23A are fabricated on the substrate 10 that has at least an insulating surface. The source 21A, channel 22A and drain 23A are PEDOT/PSS, and the channel 22A is formed on the Al gate electrode 30A formed by a vapor deposition method. The width of the channel 22A is 1 mm and the length is 100 μm, and the width of the gate electrode 30A is 100 μm, the length is 3 mm and the height is 100 nm. FIG. 2 (b) is a plan view of the transistor.

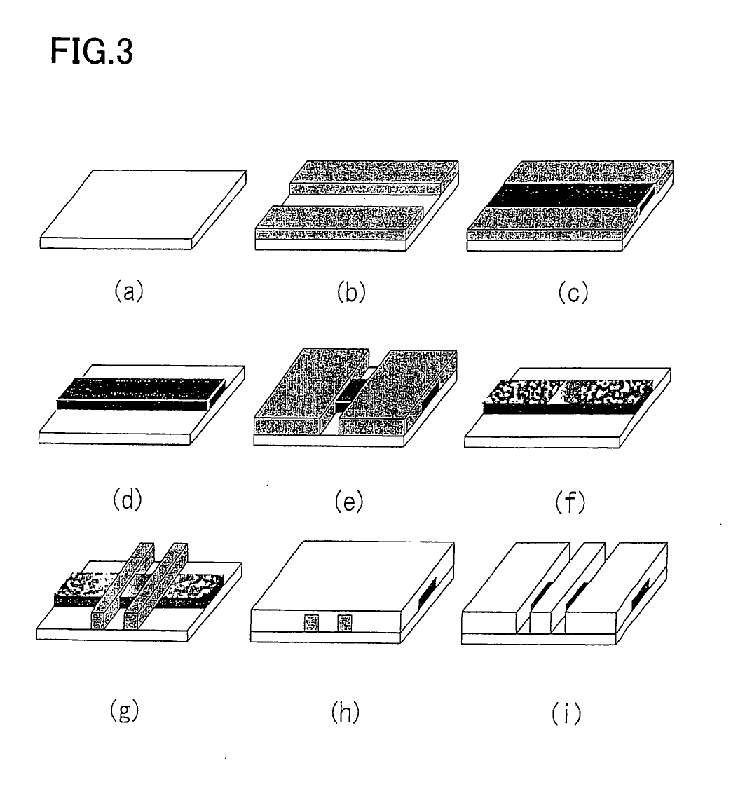

FIG. 3 illustrates the fabrication process of the Schottky gate organic field effect transistor in FIG. 1 using a laser printer. Polyethylene terephthalate (PET, 100 μm thick OHP film, Tochiman Co. Ltd.) was used for the substrate 10.

The mask as in FIG. 3 (b) was designed on a personal computer (iMac, Apple Computer Inc.) using drawing software (Illustrator, Adobe Systems Inc.) to form a source, channel and drain in 1 mm width and 3 mm length, and which was printed on a PET substrate using a commercially available laser printer (LBP-1310, Canon Inc., 1200 dpi resolution). The hatch parts in FIG. 3 (b) were the areas printed with toner of the laser printer. Additionally, an office copier can also be used instead of a laser printer, and a mask can be formed by enlarging or reducing a handwritten design.

PEDOT/PSS (Baytron P, approximately 1.3% concentration aqueous solution, H.C. Starck Ltd.) was used as the organic conductor for the source, channel and drain. 0.1 ml of PEDOT/PSS solution was aspirated with a glass Pasteur pipette (IK-PAS-5P, IWAKI Glass Inc.), and which was dropped on one end of the PET film, shown in FIG. 3 (c), where the mask for the source, channel and drain was printed. The film was coated by bar coating so that the drop of the solution was extended to the other end with a glass test tube (20 mm outside diameter, 170 mm length), and dried with hot air from a hair dryer (YD-L12, Yamada D. K. K.). Additionally, other than PDOT/PSS, any combination of the aforementioned organic semiconductors and dopants can be used as an organic conductor.

Then, toluene (first class, WAKO Inc.) was poured into a 500 ml beaker, and which was placed in an ultrasonic cleaning bath (EC-511, Twinbird Ltd.). The PET film coated with PEDOT/PSS was soaked in the toluene and cleaned by ultrasonic cleaning for 30 seconds, by which the printed toner and the PEDOT/PSS adhered to toner were removed. The important points at the time are that toner is completely removed by ultrasonic cleaning, and that PEDOT/PSS is adhered to a substrate without being peeled off. FIG. 3 (d) illustrates that PEDOT/PSS is adhered to the part for forming a source, channel and drain while the parts printed with toner are peeled off by ultrasonic cleaning.

Then, a gate mask pattern having a gap of 100 μm width and 10 mm length was designed by the same method as above, and printed over the regions of the source, channel and drain prepared by the aforementioned method. This is illustrated in FIG. 3 (e).

Although the PET film would have needed to be heated by a vacuum oven over one hour to remove the remained solvent such as water from PEDOT/PSS, desolvation occurred by heat from the heat roller of the printer in the second printing with the laser printer. This resulted in that heat treatment became unnecessary using a vacuum oven, which lead to simplifying the fabricating process. In this way, the reduction of the time of device fabrication to one-hundredth has been achieved, compared to the conventional fabrication of an organic field effect transistor by the inventor.

The technique for forming a wiring pattern of a device using a laser printer more than once as described above (hereinafter referred to as “multi-line patterning”) is applicable to the pattern formation of insulator and metal as well as organic conductor, and also, has the advantage of being capable of stacking them.

Then, when the printed toner over the source and drain regions in FIG. 3 (e) was removed by ultrasonic cleaning, the average surface roughness Rₐ of the source and drain regions reached 3 nm or more as shown in FIG. 3 (f). On the other hand, the average surface roughness Rₐ of the channel region reached 2.5 nm or less.

Then, the region being part of the source region and including the whole region contacting the channel region, and also the region being part of the drain region and including the whole region contacting the channel region were printed with toner. This is illustrated in FIG. 3 (g).

Then, an aluminum film for a gate was deposited (approximately 100 nm film thickness) using a vacuum deposition apparatus (VPC-260, ULVAC KIKO Inc.). This is illustrated in FIG. 3 (h). The film was cleaned by ultrasonic cleaning in toluene using an ultrasonic cleaning bath (EC-511, Twinbird Ltd.), by which the printed toner and the aluminum adhered to toner were removed. This is illustrated in FIG. 3 (i).

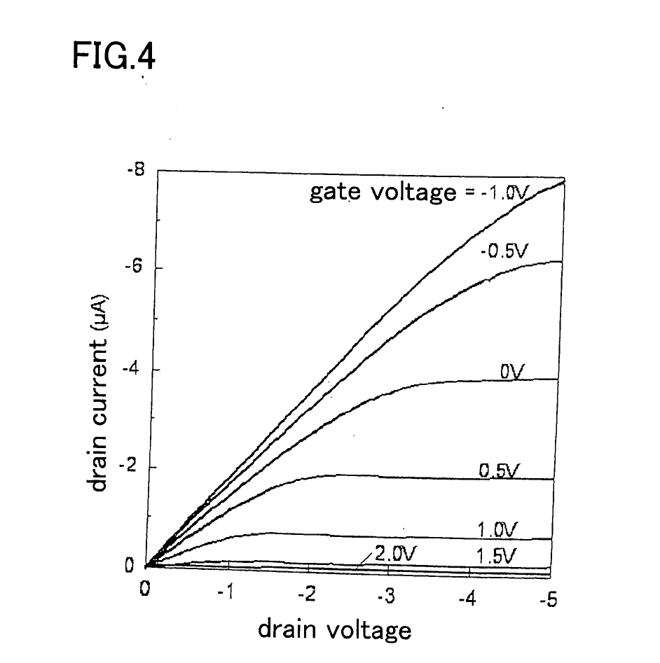

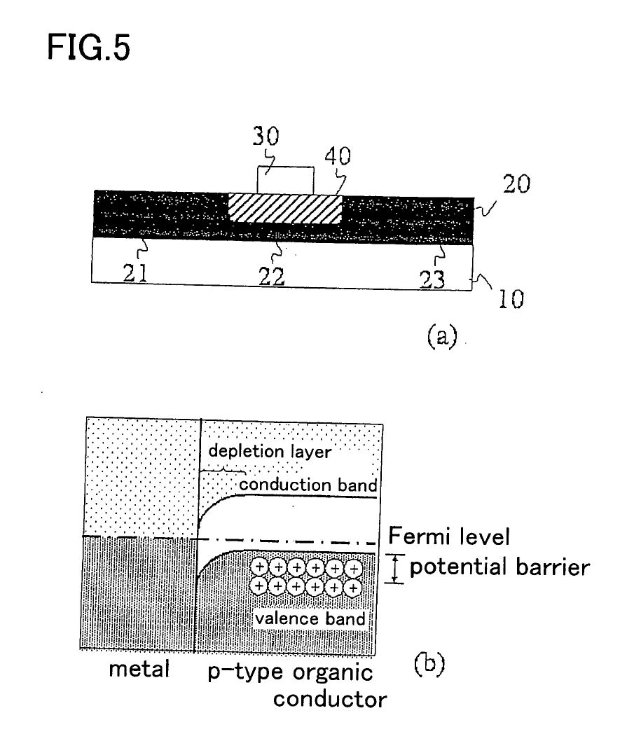

FIG. 4 shows the voltage-current characteristics of the Schottky gate organic field effect transistor obtained in this way. FIGS. 5 to 7 are diagrams speculating on the principle of operation of the Schottky gate organic transistor fabricated in the embodiment. Additionally, there has been no case of a Schottky gate organic field effect transistor doped with a dopant, and no case report describing the principle of operation of it so far.

The voltage-current characteristics were measured at room temperature and atmospheric pressure in a shielded box (HS-101, Hokuto Denko Corporation) using two picoampere meters/sources (6487, Keithley Instruments K.K.), one for the source-drain circuit and the other for the source-gate circuit, respectively.

A current of approximately 4 μm flows through the Schottky gate organic field effect transistor even if no voltage (0 V) is applied. And, the drain current increases with the drain voltage. Such characteristics are considered to result from the fact that when PEDOT/PSS comes into contact with aluminum, the Schottky barrier 40 equivalent to the difference between the work function of aluminum and the electron affinity of PEDOT/PSS is formed, but the conductive channel of PEDOT/PSS between the source and drain is thick compared to the depletion layer 40 formed by a Schottky contact as shown in FIG. 5 (a).

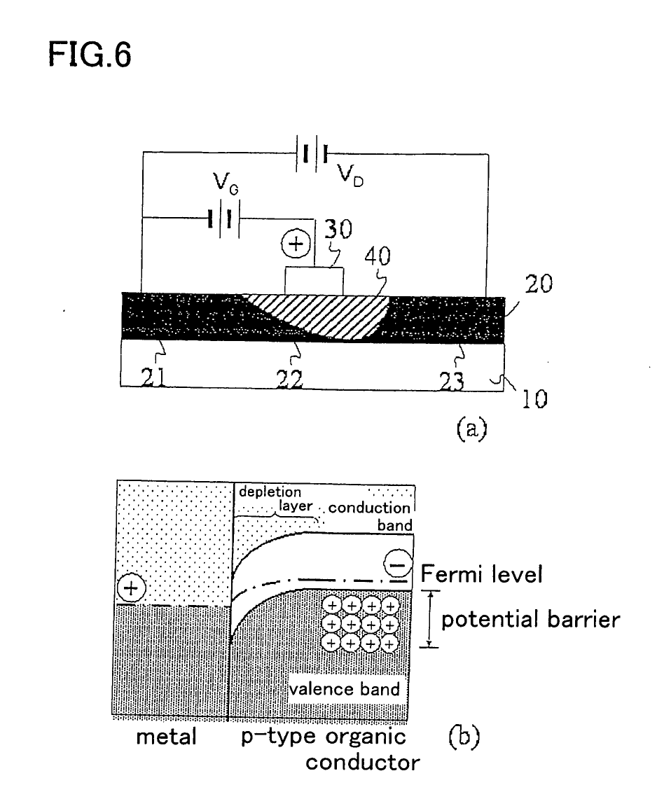

As shown in FIG. 4, when a gate voltage of 2.0 V is applied, the drain current is 0.07 μm. The reason why the drain current is pinched off with increasing the drain voltage is because the depletion layer extends since a reverse bias is applied between the drain and the gate. FIG. 6 (a) illustrates this and FIG. 6 (b) is a pattern diagram showing the speculation that if a gate voltage equivalent to reverse bias is applied, the Fermi level of the p-type organic conductor PEDOT/PSS increases and the potential barrier becomes higher, thereby the depletion layer extends and the movement of the carrier (hole) between the source and the drain is prevented, and therefore, the drain current is pinched off.

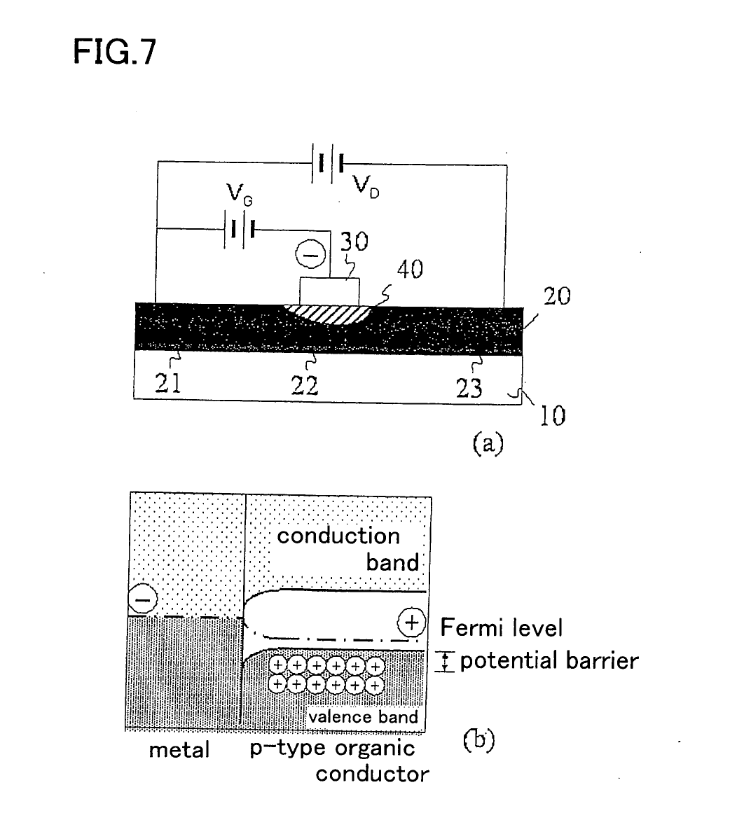

On the other hand, as shown in FIG. 4, a negative gate electrode equivalent to normal bias is applied, the drain current increases; a current of approximately −8 μA flows with −1 V (the drain voltage is −5 V). As shown in FIGS. 7 (a) and (b), the Fermi level of PEDOT/PSS decreases and the potential barrier becomes lower, and therefore the depletion layer 40 narrows. Thereby, it is considered that the movement of the carrier (hole) between the source and the drain becomes easier and the drain current increases. In this way, it has become clear that when a positive or negative gate voltage is applied, a response of depletion/enhancement type is obtained respectively. The on/off ratio of the drain current increased with the gate voltage, was approximately 100.

(Examination Case 1: Examination of the Contact State of an Interface)

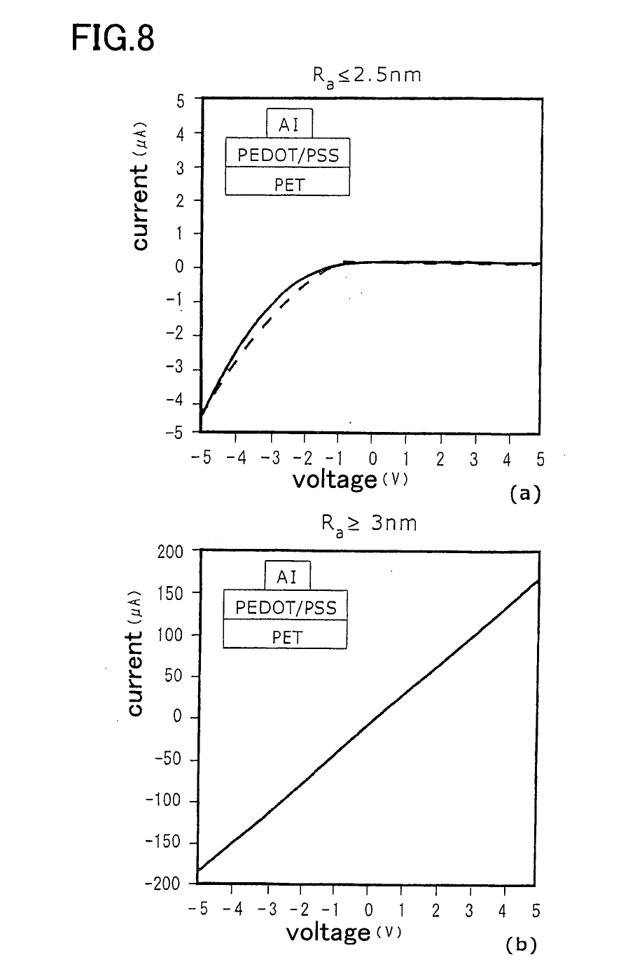

FIG. 8 is graphs showing the relationship between average surface roughness Rₐ and contact state of interface. Polyethylene terephthalate (PET, 100 μm thick OHP film, Tochiman Co. Ltd.) was used as a substrate, on which PEDOT/PSS was applied as an organic conductor, then the surface was processed so that the average surface roughness Rₐ was 2.5 mm or less, and an Al gate electrode was formed on the surface by a vapor deposition method. It has been confirmed from the voltage-current characteristics shown in FIG. 8 (a) that the contact between the organic conductor and the Al electrode was a Schottky contact.

FIG. 8 (b) shows the result of using a substrate and an organic conductor in the same way as above, then processing the surface of the organic conductor so that the average surface roughness Rₐ should be 3 mm or more, and forming an Al gate electrode on the surface by a vapor deposition method. It has been confirmed from the voltage-current characteristics shown in FIG. 8 (b) that the contact between the organic conductor and the Al electrode was an ohmic contact.

(Examination Case 2: Examination of a Field Mobility μ and a Carrier Density (NA))

An examination was performed on the carrier density of the source, channel and drain of the Schottky gate organic field effect transistor having a top gate type structure fabricated in Embodiment 1. In the conventional organic field effect transistor using an amorphous organic semiconductor for the channel, it is known that the relationship represented by Formula 1 is established between the conductivity (σ) and the carrier field mobility (μ).
μ∂σ^{δ}(δ=0.76) Formula 1

Thus, the relationship is established that the field mobility (μ) increases in proportion to the conductivity (σ) in a wide region of the conductivity ranging from 10⁻⁷ to 10⁻¹ S/cm.

Furthermore, it is known that the relationship represented by Formula 2 is established between the conductivity (σ) and the dopant concentration (Nd), and that the relationship represented by Formula 3 is established among the conductivity (σ) of a bulk organic semiconductor, the carrier density (NA) and the carrier mobility (μ).
σ=N_{d}^{γ}(γ=4.5) Formula 2
σ=N_{A}×e×μ Formula 3

From the above, it becomes evident that both the conductivity (σ) and the mobility (μ) of organic semiconductor increase with increasing the dopant concentration (Nd) or the carrier density (NA). Additionally, it is considered that approximately 1% of applied dopant contributes to carrier generation (Synthetic Metals, 68, 65-70, 1994).

In a Schottky gate type FET (field effect transistor), there is a relationship represented by Formula 4 among the saturated drain current (I_{Dsat}), the carrier mobility (μ) and the gate voltage (VG), from which the enhancement of carrier mobility is a requirement for the improvement of characteristics such as achieving high current, fast response and low voltage drive.

$${I}_{Dsai} \approx \frac{W {μɛ}_{s}}{2 dL} {( {V}_{G} - {V}_{T} )}^{2} \qquad Formula 4$$

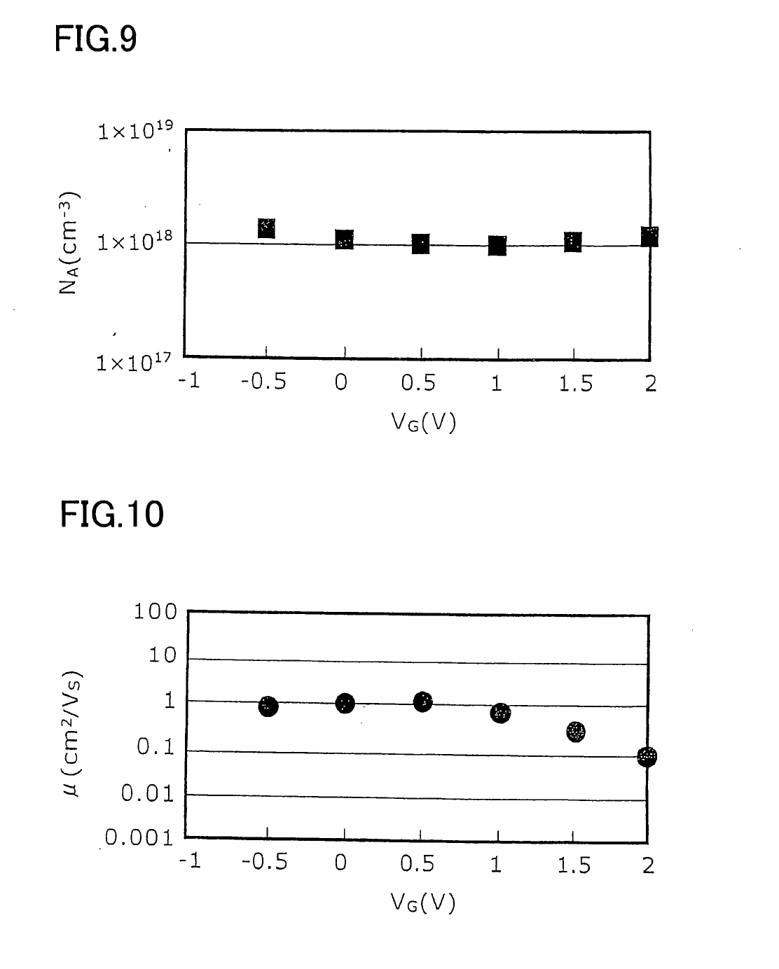

FIG. 9 is a graph showing the dependence of carrier density (NA) on gate voltage (VG), which carrier density is calculated from Formula 5 using the pinch-off voltage (VP) in the current-voltage curve (characteristic curve shown in FIG. 4) of the Schottky gate organic field effect transistor fabricated in Embodiment 1. In the formula, q is the elementary charge (1.602×10⁻¹⁹ C), ∈ₛ is the dielectric constant of the channel (3×8.854×10⁻¹⁴ F/cm), and d is the channel thickness (34 nm).

$${N}_{A} = \frac{2 {ɛ}_{s} {V}_{p}}{{qd}^{ 2}} \qquad Formula 5$$

As shown in FIG. 9, N_{A} was nearly constant around 10¹⁸ cm⁻³ regardless of the gate voltage. The value is 1000 times higher than that of a common silicon semiconductor (10¹⁵ cm⁻³). FIG. 10 is a graph showing the dependence of carrier mobility (μ) on gate voltage, which carrier mobility is calculated from Formula 6 using the pinch-off current (IP). In the formula, q is the elementary charge (1.602×10⁻¹⁹ C), ∈ₛ is the dielectric constant of the channel (3×8.854×10⁻¹⁴ F/cm), d is the channel thickness (34 nm), L is the gate length (1 mm), and W is the gate width (135 μm).

$$μ = \frac{2 {ɛ}_{s} {LI}_{p}}{{Wq}^{2} {N}_{A}^{2} {d}^{3}} \qquad Formula 6$$

As shown in FIG. 10, μ was 0.1-1 cm²/Vs though there was a certain range depending on the gate voltage. The value is approximately consistent with the mobility (μ=1 cm²/Vs) expected from the conductivity of PEDOT/PSS (σ=3.5 S/cm) in FIG. 4, and 10-10⁻⁸ times greater than that of a conventional polymer semiconductor (10⁻⁸-10⁻² cm²/Vs)

### INDUSTRIAL APPLICABILITY

If the Schottky gate organic field effect transistor is used for a drive circuit for a display, a lightweight and flexible display of total organic type can be manufactured. Also, the Schottky gate organic field effect transistor can be used for a drive circuit for an IC tag or a conventional liquid crystal display.

1. A Schottky gate organic field effect transistor comprising:
a source, a channel and a drain formed by one organic conductive material and formed continuously in an organic conductor;
a gate electrode formed on one surface of the organic conductor and functioning as a metal gate; and
a Schottky barrier formed by contact between the gate electrode and the organic conductor,
the channel being a region overlapping with the Schottky barrier.

2. The Schottky gate organic field effect transistor of claim 1, wherein the organic conductive material has a carrier density of 10¹⁸/cm³ or more

3. The Schottky gate organic field effect transistor of claim 1, having a field mobility of 0.1 cm²/Vs or more.

4. The Schottky gate organic field effect transistor of any one of claims 1 to 3, wherein the organic conductive material is poly(3,4-ethylenedioxythiophene).

5. The Schottky gate organic field effect transistor of claim 4, wherein an average surface roughness Rₐ of a contact surface of the gate electrode before the contact and/or a contact surface of the channel before the contact is 2.5 nm or less.

6. The Schottky gate organic field effect transistor of claim 1,
on the source, a source electrode being formed of a metal material identical to a metal material of the gate electrode,
on the drain, a drain electrode being formed of a metal material identical to the metal material of the gate electrode,
the source electrode and the drain electrode being formed at respective sides of the gate electrode so as not to overlap each other,
the organic conductive material being poly(3,4-ethylenedioxythiophene), and
an average surface roughness Rₐ of a contact surface of the source before contact and/or a contact surface of the source electrode before the contact and an average surface roughness Rₐ of a contact surface of the drain before contact and/or a contact surface of the drain electrode before the contact being 3.0 nm or more.

7. The Schottky gate organic field effect transistor of claim 1, being fabricated by a method including:
printing a negative pattern of a first pattern of the source, the channel and the drain continuously formed to operate on a substrate having at least an insulating surface by use of a printing material soluble in a solvent;
applying the organic conductive material so as to cover at least the first pattern and cleaning the substrate;
printing a second pattern covering the source and the drain and cleaning the substrate by a solvent;
printing a negative pattern of a third pattern specifying a region functioning as a source electrode on the source, a region functioning as the gate electrode on the channel and a region functioning as a drain electrode on the drain, and depositing a metal material so as to cover at least the third pattern; and
then, cleaning the substrate.

8. A Schottky gate organic field effect transistor being fabricated by a method including:
forming on a substrate having at least an insulating surface, a source electrode, a gate electrode and a drain electrode made of a metal material in such a manner that the source electrode, the gate electrode and the drain electrode are independent from each other and the source electrode and the drain electrode are formed at the respective sides of the gate electrode;
roughening each surface of the source electrode and the drain electrode; and
applying an organic conductive material so as for the source electrode, the gate electrode and the drain electrode to have a continuous structure.

9. A fabrication method of the Schottky gate organic field effect transistor of claim 7, wherein the printing is performed by a laser printer and the printing material is a toner.

10. A fabrication of the Schottky gate organic field effect transistor of claim 7, wherein the metal material is aluminum.

11. An ohmic contact forming method comprising:
preparing an organic conductive material and a metal material such that a Schottky contact is formed between the organic conductive material and the metal material if a surface of the organic conductive material is flat and the metal material is deposited on the flat surface of the organic conductive material;
processing the surface of the organic conductive material so as to have an average surface roughness Rₐ greater than or equal to a predetermined value; and
depositing the metal material on the processed surface of the organic conductive material to form an ohmic contact between the metal material and the organic conductive material.

12. The ohmic contact forming method of claim 11, wherein the predetermined value of the average surface roughness Rₐ is 3 nm.

13. The ohmic contact forming method of claim 11 or 12, wherein the organic conductive material is poly(3,4-ethylenedioxythiophene).

14. An ohmic contact forming method comprising:
preparing an organic conductive material and a metal material such that a Schottky contact is formed between the organic conductive material and the metal material if a surface of the metal material is flat and the organic conductive material is applied on the flat surface of the metal material;
processing the surface of the metal material so as to have an average surface roughness Rₐ greater than or equal to a predetermined value; and
applying the organic conductive material on the processed surface of the metal material to form an ohmic contact between the metal material and the organic conductive material.

15. The ohmic contact forming method of claim 14, wherein the predetermined value of the average surface roughness Rₐ is 3 nm.

16. The ohmic contact forming method of claim 14 or 15, wherein the organic conductive material is poly(3,4-ethylenedioxythiophene).
